(19) United States
(12) Patent Application Publication
(10) Pub. No.: US 2010/0227457 A1
(43) Pub. Date: Sep. 9, 2010

(54) Method of forming phase change material layer and method of fabricating phase change memory device

(76) Inventors: Hyeonggeun An, Hwaseong-si (KR); Sunglae Cho, Gwacheon-si (KR); Dong-Hyun Im, Hwaseong-si (KR); Jinil Lee, Seongnam-si (KR)

Correspondence Address: LEE & MORSE, P.C., 3141 FAIRVIEW PARK DRIVE, SUITE 500, FALLS CHURCH, VA, 22042, US

(21) Appl. No.: 12/659,262

(22) Filed: Mar. 2, 2010

(30) Foreign Application Priority Data
Mar. 3, 2009 (KR) 10-2009-0018138

(51) Int. Cl. H01L 21/04

(52) U.S. Cl. 438/483; 257/E21.102

(57) ABSTRACT

A method of forming a phase change material layer and a method of fabricating a phase change memory device, the method of forming a phase change material layer including forming an amorphous germanium layer by supplying a germanium containing first source into a reaction chamber; cutting off supplying the first source after forming the amorphous germanium layer; and forming amorphous Ge₁₋ₓTeₓ (0<x≦0.5) such that forming the amorphous Ge₁₋ₓTeₓ (0<x≦0.5) includes supplying a tellurium containing second source into the reaction chamber after cutting off supplying the first source.

### BACKGROUND

1. Field

Embodiments relate to a method of forming a phase change material layer and a method of fabricating a phase change memory device.

2. Description of Related Art

In general, semiconductor memory devices may be classified as volatile memory devices and nonvolatile memory devices. The nonvolatile memory devices may retain their stored data even when their power supplies are interrupted. Nonvolatile memory devices may include, e.g., programmable ROM (PROM), erasable PROM (EPROM), electrically EPROM (EEPROM), and flash memory. Recently, there has been an increasing demand for non-volatile memory devices that can be electrically programmed and erased.

Variable resistance memory devices, e.g., resistive random access memory (ReRAM) and phase-change random access memory (PRAM), have been developed as nonvolatile memory devices. Materials constituting variable resistance semiconductor memory devices may be characterized in that their resistance may be varied by application of current/voltage, and may be maintained even when the current or voltage is cut off.

PRAM uses a phase change material, e.g., a chalcogenide material. The phase change material may be in either a crystalline state or an amorphous state. If a phase change material in an amorphous state is heated to a temperature between a crystallization temperature and a melting point for a predetermined time and then cooled, it may transition to the crystalline state from the amorphous state (set programming). On the other hand, if the phase change material is heated to a relatively high temperature, e.g., above the melting point, and quickly cooled, it may transition to an amorphous state from a crystalline state (reset programming).

Several approaches have been taken to apply write current of relatively great value during reset programming. One of the approaches is that a contact area between a heating electrode and the phase change material may be reduced to increase an effective current density. After forming a minute hole to expose a bottom electrode, a phase change material may be formed in the hole to reduce a contact area between the heating electrode and the phase change material.

### SUMMARY

Embodiments are directed to a method of forming a phase change material layer and a method of fabricating a phase change memory device, which represent advances over the related art.

It is a feature of an embodiment to provide a method of forming a phase change material layer that is capable of being deposited minutely and conformally without voids.

At least one of the above and other features and advantages may be realized by providing a method of forming a phase change material layer, the method including forming an amorphous germanium layer by supplying a germanium containing first source into a reaction chamber; cutting off supplying the first source after forming the amorphous germanium layer; and forming amorphous Ge₁₋ₓTeₓ (0<x≦0.5) such that forming the amorphous Ge₁₋ₓTeₓ (0<x≦0.5) includes supplying a tellurium containing second source into the reaction chamber after cutting off supplying the first source.

The amorphous Ge₁₋ₓTeₓ (0<x≦0.5) may be formed at a temperature of about 300° C. or greater.

The amorphous Ge₁₋ₓTeₓ (0<x≦0.5) may be formed at a temperature of about 300° C. to about 400° C.

The first source may include at least one of an amide ligand, a phosphanido ligand, an alkoxide ligand, and a thiolate ligand.

The method may further include supplying a reactive gas into the reaction chamber, the reactive gas including at least one of ammonia, primary amine, diazene, and hydrazine.

The method may further include supplying an antimony containing third source into the reaction chamber.

The third source may be supplied after supplying the second source.

The method may further include sequentially supplying additional second source and first source after supplying the third source.

The method may further include supplying additional second source at the same time as supplying the third source.

The third source and second source may be supplied at the same time.

The method may further include forming an amorphous layer of Sb₁₋ₓTeₓ (0<x<1) on the amorphous Ge₁₋ₓTeₓ (0<x≦0.5).

The method may further include purging the reaction chamber between supplying sources.

At least one of the above and other features and advantages may also be realized by providing a method of fabricating a phase change memory device, the method including providing a substrate having a bottom electrode; forming an insulating layer having an opening such that the opening exposes the bottom electrode; forming an amorphous germanium layer by supplying a germanium containing first source into the opening; cutting off supplying the first source after forming the amorphous germanium layer; and forming amorphous Ge₁₋ₓTeₓ (0<x≦0.5) such that forming the amorphous Ge₁₋ₓTeₓ (0<x≦0.5) includes supplying a tellurium containing second source onto the substrate to after cutting off supplying the first source.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a flowchart of a method of forming a phase change material layer according to an embodiment;

FIG. 2 illustrates a source supply diagram of the method of forming a phase change material layer of FIG. 1;

FIG. 3A illustrates a surface SEM image of a comparative phase change material layer;

FIG. 3B illustrates a surface SEM image of a phase change material layer formed according to the method of FIG. 1;

FIG. 4 illustrates a flowchart of a method of forming a phase change material layer according to another embodiment;

FIG. 5 illustrates a source supply diagram of the method of forming a phase change material layer of FIG. 4;

FIG. 6 illustrates a surface SEM image of a phase change material formed according to the method of FIG. 4;

FIG. 7 illustrates a flowchart of a method of forming a phase change material layer according to yet another embodiment;

FIG. 8 illustrates a source supply diagram of the method of forming a phase change material layer of FIG. 7;

FIG. 9 illustrates a surface SEM image of a phase change material formed according to the method of FIG. 7;

FIGS. 10 to 13 illustrate stages in a method of forming a phase change memory device according to an embodiment;

FIG. 14 illustrates a result of an endurance test for a phase change memory device formed according to the method of an embodiment;

FIG. 15 illustrates a memory card system including phase change memory devices according to an embodiment; and

FIG. 16 illustrates an electronic system including phase change memory devices according to an embodiment.

### DETAILED DESCRIPTION

Korean Patent Application No. 10-2009-0018138, filed on Mar. 3, 2009, in the Korean Intellectual Property Office, and entitled: “Method of Forming Phase Change Material Layer,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

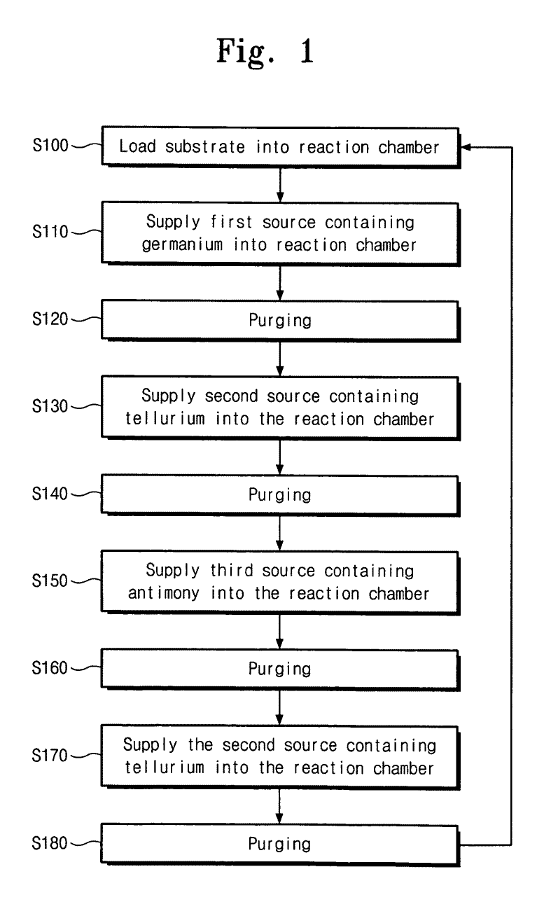

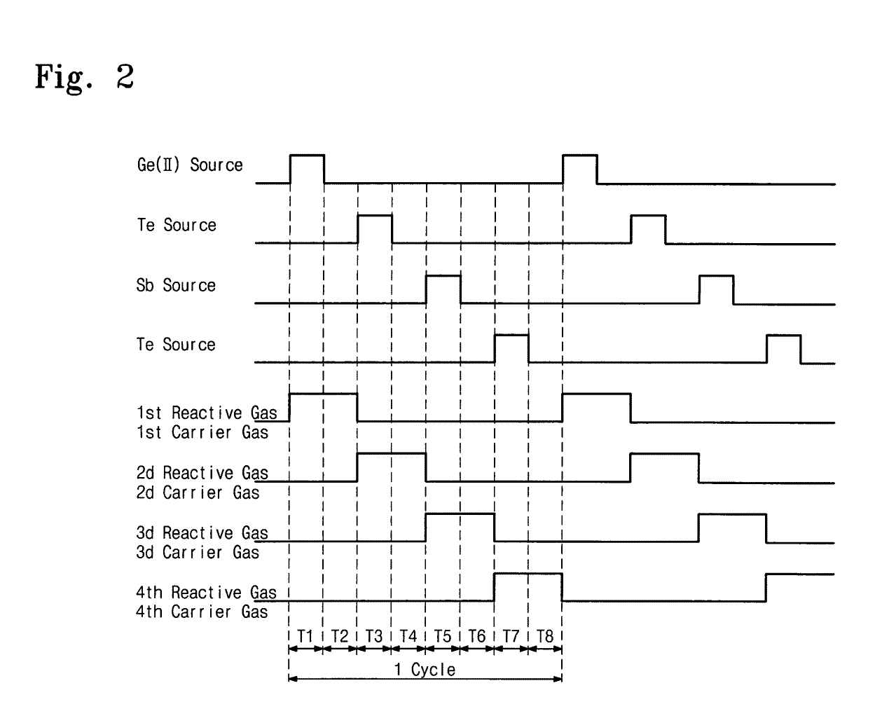

Referring to FIGS. 1 and 2, a method of forming a phase change material layer according to an embodiment will now be described in detail. In an implementation, the phase change material layer may be formed by atomic layer deposition (ALD). A substrate may be loaded into a reaction chamber (S100). The substrate may be a semiconductor-based substrate. The substrate may include a conductive area and/or an insulating area. The conductive area may include a conductive layer. The conductive layer may be made of, e.g., titanium, titanium nitride, aluminum, thallium, thallium nitride, and/or titanium aluminum nitride. The insulating area may include an inorganic layer. The inorganic layer may be made of, e.g., silicon oxide, titanium oxide, aluminum oxide, zirconium oxide, and/or hafnium oxide. In an implementation, the substrate may be heated to a temperature of, e.g., about 300 degrees centigrade (° C.) or greater. In another implementation, the substrate may be heated to a temperature of, e.g., about 300° C. to about 400° C.

For a time T1, a first reactive gas may be supplied into the reaction chamber (S110). The first reactive gas may include a functional group represented by —NR₁R₂ (wherein R₁ and R₂ may each independently be, e.g., H, CH₃, C₂H₅, C₃H₇, C₄H₉, or Si(CH₃)₄). The first reactive gas may include, e.g., an —NH₂ group. In an implementation, the first reactive gas may include, e.g., ammonia, primary amine, diazene, and hydrazine. In another implementation, the first reactive gas may include, e.g., NH₃ (ammonia) or N₂H₂ (diazene).

A first source, containing germanium, may be supplied into the reaction chamber before, after, or at the same time the first reactive gas is supplied. For example, for the time T1, the first source may be supplied. The first source may be carried by a first carrier gas. The first source may be a Ge(II) source (wherein the “Ge(II)” means that an oxidation state of germanium is +2). The first source may include, e.g., amide ligand, phosphanido ligand, alkoxide ligand, and/or thiolate ligand. In an implementation, the first source may include, e.g., Ge[(iPr)₂Amid(Bu)]₂, Ge(MABO)₂, and/or Ge(MAPO)₂. In another implementation, the first source may include only a germanium containing compound. In yet another implementation, the first source may consist essentially of the germanium containing compound. As a result, a thin film of N-doped amorphous germanium may be formed on the substrate.

For a time T2, the supply of the first source may be cut off and the first carrier gas and/or the first reactive gas may continue to be supplied into the reaction chamber. In an implementation, the first reactive gas may also be cut off at time T2. Thus, physically adsorbed first source and unreacted first source may be purged (S120).

For a time T3, a second source may be supplied into the reaction chamber (S130). The second source may include tellurium (Te). In an implementation, the second source may include, e.g., Te(CH₃)₂, Te(C₂H₅)₂, Te(n-C₃H₇)₂, Te(i-C₃H₇)₂, Te(t-C₄H₉)₂, Te(i-C₄H₉)₂, Te(CH═CH₂)₂, Te(CH₂CH═CH₂)₂, and/or Te[N(Si(CH₃)₃)₂]₂. The second source may be carried by a second carrier gas. A second reactive gas may be supplied before, after, or at the same time the second source is supplied. The second reactive gas may include, e.g., hydrogen (H₂), oxygen (O₂), ozone (O₃), steam (H₂O), silane (SiH₄), diborane (B₂H₆), hydrazine (N₂H₄), primary amine, and/or ammonia (NH₃). As a result, a phase change material layer of N-doped amorphous Ge₁₋ₓTeₓ (0<x≦0.5), i.e., having a tellurium content of about 50 percent or less, may be formed on the substrate. In other words, the N-doped amorphous Ge₁₋ₓTeₓ (0<x≦0.5) may have a up to 50 percent Te, but not above.

For a time T4, the supply of the second source may be cut off and the second carrier gas and/or the second reactive gas may continue to be supplied into the reaction chamber. In an implementation, the second reactive gas may also be cut off at time T4. Thus, physically adsorbed second source and unreacted second source may be purged (S140).

For a time T5, a third source may be supplied into the reaction chamber (S150). The third source may include antimony (Sb). In an implementation, the third source may include, e.g., Sb(CH₃)₃, Sb(C₂H₅)₃, Sb(i-C₃H₇)₃, Sb(n-C₃H₇)₃, Sb(i-C₄H₉)₃, Sb(t-C₄H₉)₃, Sb(N(CH₃)₂)₃, Sb(N(CH₃)(C₂H₅))₃, Sb(N(C₂H₅)₂)₃, Sb(N(i-C₃H₇)₂)₃, and/or Sb[N(Si(CH₃)₃)₂]₃. The third source may be carried by a third carrier gas. A third reactive gas may be supplied before, after, or at the same the third source is supplied. The third reactive gas may include, e.g., hydrogen (H₂), oxygen (O₂), ozone (O₃), steam (H₂O), silane (SiH₄), diborane (B₂H₆), hydrazine (N₂H₄), primary amine, and/or ammonia (NH₃). As a result, a layer of Sb₁₋ₓTeₓ (0<x<1) may be formed on the layer of amorphous Ge₁₋ₓTeₓ (0<x≦0.5) to form a phase change material layer of N-doped amorphous Ge—Sb—Te on the substrate.

For a time T6, the supply of the third source may be cut off and the third carrier gas and/or the third reactive gas may continue to be supplied into the reaction chamber. In an implementation, the third reactive gas may also be cut off at time T6. Thus, physically adsorbed third source and unreacted third source may be purged (S160).

For a time T7, the second source may again be supplied into the reaction chamber (S170). As described above, the second source may include tellurium (Te). In an implementation, the additional second source may include, e.g., Te(CH₃)₂, Te(C₂H₅)₂, Te(n-C₃H₇)₂, Te(i-C₃H₇)₂, Te(t-C₄H₉)₂, Te(i-C₄H₉)₂, Te(CH═CH₂)₂, Te(CH₂CH═CH₂)₂, and/or Te[N(Si(CH₃)₃)₂]₂. The second source may be carried by a fourth carrier gas. A fourth reactive gas may be supplied before, after, or at the same time the second source is supplied. The fourth reactive gas may include, e.g., hydrogen (H₂), oxygen (O₂), ozone (O₃), steam (H₂O), silane (SiH₄), diborane (B₂H₆), hydrazine (N₂H₄), primary amine, and/or ammonia (NH₃).

For a time T8, the supply of the additional second source may be cut off and the fourth carrier gas and/or the fourth reactive gas may continue to be supplied into the reaction chamber. In an implementation, the fourth reactive gas may also be cut off at time T8. Thus, physically adsorbed second source and an unreacted second source may be purged (S180).

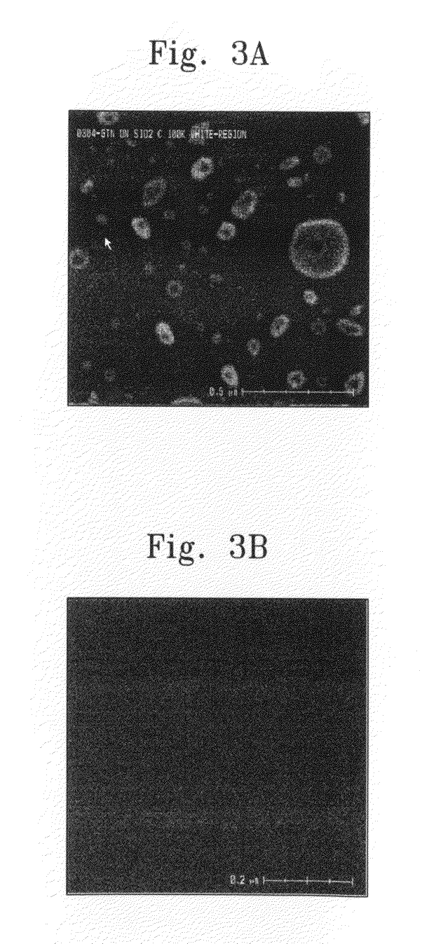

In an implementation, the sequence of S110 to S180 (T1-T8) may represent one cycle. The cycle may be one or more additional times, depending on a desired thickness of the phase change material layer. The phase change material layer of N-doped amorphous Ge—Sb—Te according to an embodiment may have a superior characteristic in that, e.g., a crystalline structure may not be visible (see FIG. 3B).

There may be difficulty in reacting antimony from the third source provided during S150 with germanium from the first source provided during S110. Accordingly, the tellurium (second) source is preferably supplied again during S170.

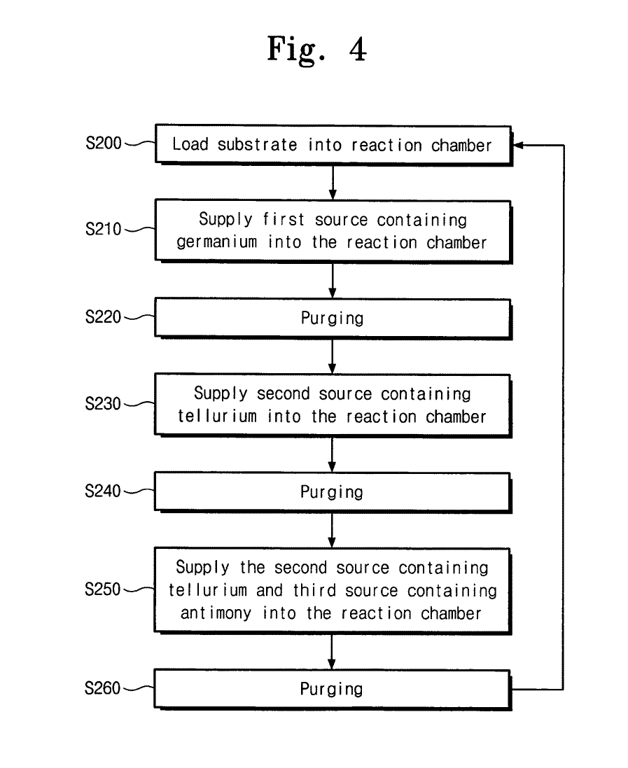

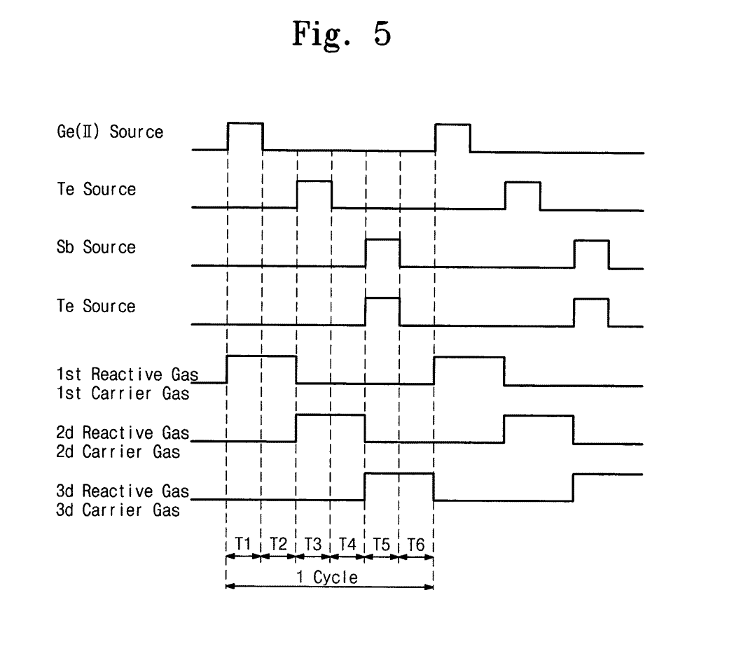

Referring to FIGS. 4 and 5, a method of forming a phase change material layer according to another embodiment will now be described in detail. In order to avoid repetition, the following explanations relate only to aspects that are different from FIGS. 1 and 2.

A substrate may be loaded into a reaction chamber (S200). The substrate may be a semiconductor-based substrate. In an implementation, the substrate may be heated to a temperature of, e.g., about 300° C. or greater. In another implementation, the substrate may be heated to a temperature of, e.g., about 300° C. to about 400° C.

For a time T1, a first reactive gas may be supplied into the reaction chamber (S210). The first reactive gas may include a functional group represented by —NR₁R₂ (wherein R₁ and R₂ may each independently be H, CH₃, C₂H₅, C₃H₇, C₄H₉, and/or Si(CH₃)₄). In an implementation first reactive gas may include, e.g., an —NH₂ group. In another implementation, the first reactive gas may include, e.g., ammonia, primary amine, diazene, and/or hydrazine.

A first source, containing germanium, may be supplied into the reaction chamber before, after, or at the same time the first reactive gas is supplied. For example, for the time T1, the first source may be supplied. The first source may be carried by a first carrier gas. The first source may be a Ge(II) source. In an implementation, first source may include, e.g., amide ligand, phosphanido ligand, alkoxide ligand, and/or thiolate ligand. In another implementation, the first source may include, e.g., Ge[(iPr)₂Amid(Bu)]₂, Ge(MABO)₂, and/or Ge(MAPO)₂. As a result, a thin film of N-doped amorphous germanium may be formed on the substrate.

For a time T2, the supply of the first source may be cut off and the first carrier gas and/or the first reactive gas may continue to be supplied into the reaction chamber. In an implementation, the first reactive gas may also be cut off at time T2. Thus, physically adsorbed first source and unreacted first source may be purged (S220).

For a time T3, a second source may be supplied into the reaction chamber (S230). The second source may include tellurium (Te). In an implementation, the second source may include, e.g., Te(CH₃)₂, Te(C₂H₅)₂, Te(n-C₃H₇)₂, Te(i-C₃H₇)₂, Te(t-C₄H₉)₂, Te(i-C₄H₉)₂, Te(CH═CH₂)₂, Te(CH₂CH═CH₂)₂, and/or Te[N(Si(CH₃)₃)₂]₂. The second source may be carried by a second carrier gas. A second reactive gas may be supplied before, after, or at the same time the second source is supplied. As a result, a phase change material layer of N-doped amorphous Ge₁₋ₓTeₓ (0<x≦0.5),), i.e., having a tellurium content of about 50 percent or less, may be formed on the substrate.

For a time T4, the supply of the second source may be cut off and the second carrier gas and/or the second reactive gas may continue to be supplied into the reaction chamber. In an implementation, the second reactive gas may also be cut off at time T4. Thus, physically adsorbed second source and unreacted second source may be purged (S240).

For a time T5, a third source and additional second source may be simultaneously supplied into the reaction chamber (S250). The third source may include antimony (Sb). In an implementation, the third source may include, e.g., Sb(CH₃)₃, Sb(C₂H₅)₃, Sb(i-C₃H₇)₃, Sb(n-C₃H₇)₃, Sb(i-C₄H₉)₃, Sb(t-C₄H₉)₃, Sb(N(CH₃)₂)₃, Sb(N(CH₃)(C₂H₅))₃, Sb(N(C₂H₅)₂)₃, Sb(N(i-C₃H₇)₂)₃ or Sb[N(Si(CH₃)₃)₂]₃. Sb(CH₃)₃, Sb(C₂H₅)₃, Sb(i-C₃H₇)₃, Sb(n-C₃H₇)₃, Sb(i-C₄H₉)₃, Sb(t-C₄H₉)₃, Sb(N(CH₃)₂)₃, Sb(N(CH₃)(C₂H₅))₃, Sb(N(C₂H₅)₂)₃, Sb(N(i-C₃H₇)₂)₃, and/or Sb[N(Si(CH₃)₃)₂]₃. The third source and additional second source may be carried by a third carrier gas. A third reactive gas may be supplied before, after, or at the same the second and third sources are supplied. As a result, a layer of Sb₁₋ₓTeₓ (0<x<1) may be formed on the layer of amorphous Ge₁₋ₓTeₓ (0<x≦0.5) to form a phase change material layer of N-doped amorphous Ge—Sb—Te on the substrate.

For a time T6, the supply of the second and third sources may be cut off and the third carrier gas and/or the third reactive gas may continue to be supplied into the reaction chamber. In an implementation, the third reactive gas may also be cut off at time T6. Thus, physically adsorbed second and third source as well as unreacted second and third source may be purged (S260).

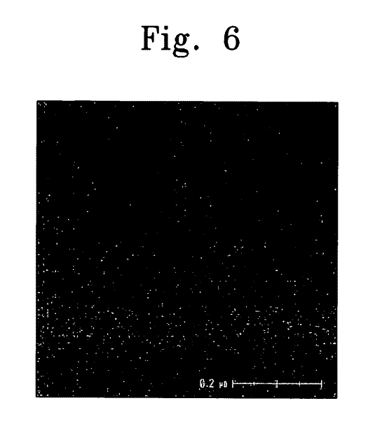

In an implementation, the sequence of S210 to S260 (T1-T6) may represent one cycle. The cycle may be performed one or more additional times, depending on a desired thickness of the phase change material layer. The phase change material layer of N-doped amorphous Ge—Sb—Te according to the present embodiment may have a superior characteristic in that, e.g., a crystalline structure may not be visible (see FIG. 6).

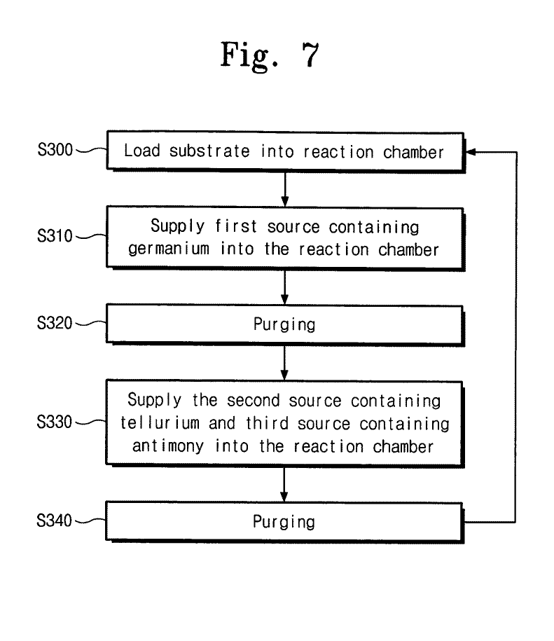

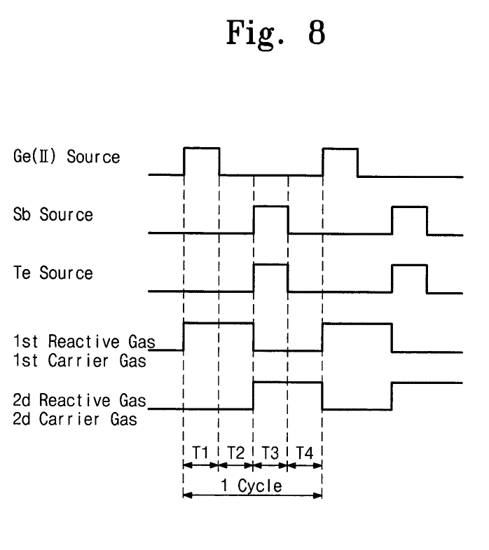

Referring to FIGS. 7 and 8, a method of forming a phase change material layer according to yet another embodiment will now be described in detail. In order to avoid repetition, the following explanations relate only to aspects that are different from FIGS. 1 and 2.

A substrate may be loaded into a reaction chamber (S200). The substrate may be a semiconductor-based substrate. The substrate may be heated to a temperature of, e.g., greater than about 300° C. In an implementation, the substrate may be heated to a temperature of, e.g., about 300° C. to about 400° C.

For a time T1, a first reactive gas may be supplied into the reaction chamber (S310). The first reactive gas may include a functional group represented by —NR₁R₂ (wherein R₁ and R₂ may each independently be, e.g., H, CH₃, C₂H₅, C₄H₉, and/or Si(CH₃)₄). In an implementation, the first reactive gas may include, e.g., an —NH₂ group. In another implementation, the first reactive gas may include, e.g., ammonia, primary amine, diazene, and/or hydrazine.

A first source, containing germanium, may be supplied into the reaction chamber before, after, or at the same time as the first reactive gas is supplied. For example, for the time T1, the first source may be supplied. The first source may be carried by a first carrier gas. The first source may be a Ge(II) source. The first source may include, e.g., amide ligand, phosphanido ligand, alkoxide ligand, and/or thiolate ligand. In an implementation, the first source may include, e.g., Ge[(iPr)₂Amid(Bu)]₂, Ge(MABO)₂, and/or Ge(MAPO)₂. As a result, a thin film of N-doped amorphous germanium may be formed on the substrate.

For a time T2, the supply of the first source may be cut off and the first carrier gas and/or the first reactive gas may continue to be supplied into the reaction chamber. In an implementation, the fourth reactive gas may also be cut off at time T2. Thus, physically adsorbed first source and unreacted first source may be purged (S320).

For a time T3, a second source and a third source may be simultaneously supplied into the reaction chamber (S330). The second source may include tellurium (Te). In an implementation, the second source may include, e.g., Te(CH₃)₂, Te(C₂H₅)₂, Te(n-C₃H₇)₂, Te(i-C₃H₇)₂, Te(t-C₄H₉)₂, Te(i-C₄H₉)₂, Te(CH═CH₂)₂, Te(CH₂CH═CH₂)₂, and/or Te[N(Si(CH₃)₃)₂]₂. The third source may include antimony (Sb). In an implementation, the third source may include, e.g., Sb(CH₃)₃, Sb(C₂H₅)₃, Sb(i-C₃H₇)₃, Sb(n-C₃H₇)₃, Sb(i-C₄H₉)₃, Sb(t-C₄H₉)₃, Sb(N(CH₃)₂)₃, Sb(N(CH₃)(C₂H₅))₃, Sb(N(C₂H₅)₂)₃, Sb(N(i-C₃H₇)₂)₃ or Sb[N(Si(CH₃)₃)₂]₃. Sb(CH₃)₃, Sb(C₂H₅)₃, Sb(i-C₃H₇)₃, Sb(n-C₃H₇)₃, Sb(i-C₄H₉)₃, Sb(t-C₄H₉)₃, Sb(N(CH₃)₂)₃, Sb(N(CH₃)(C₂H₅))₃, Sb(N(C₂H₅)₂)₃, Sb(N(i-C₃H₇)₂)₃, and/or Sb[N(Si(CH₃)₃)₂]₃. The second and third sources may be carried by a second carrier gas. A second reactive gas may be supplied before, after, or at the same time the second and third sources are supplied. As a result, a layer of Sb₁₋ₓTeₓ (0<x<1) may be formed on a layer of amorphous Ge₁₋ₓTeₓ (0<x≦0.5) to form a phase change material layer of N-doped amorphous Ge—Sb—Te on the substrate.

For a time T4, the supply of the second and third sources may be cut off and the second carrier gas and/or the second reactive gas may continue to be supplied into the reaction chamber. In an implementation, the second reactive gas may also be cut off at time T4. Thus, physically adsorbed second and third source as well as unreacted second and third source may be purged (S340).

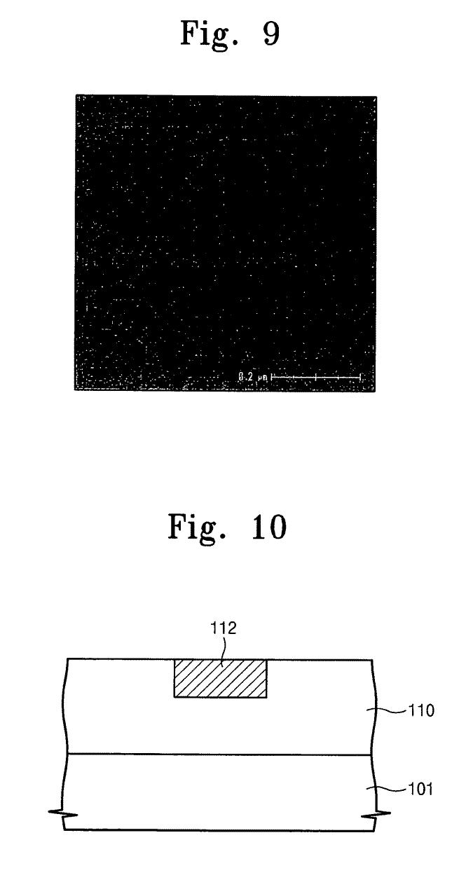

In an implementation, the sequence of S310 to S340 (T1-T4) may represent one cycle. The cycle may be performed one or more additional times, depending on a desired thickness of the phase change material layer. The phase change material layer of N-doped amorphous Ge—Sb—Te according to the present embodiment may exhibit a superior characteristic in that, e.g., a crystalline structure may not be visible (see FIG. 9).

In the above described embodiments, the first to third sources may be carried by the first to fourth carrier gases. Each of the carrier gases may be an inert gas including, e.g., argon (Ar), helium (He), and/or nitrogen (N₂). In an alternative implementation, the first to third sources may be supplied into the reaction chamber after being dissolved in respective solvents and rapidly vaporized using a vaporizer.

In the above described embodiments, the reactive gases may be supplied simultaneously with the sources. However, the embodiments are not limited thereto. For example, a thin film may be deposited by the sources without the respective reactive gases and then treated with plasma of the reactive gases (e.g., NH₃ plasma).

Generally, when a layer of N-doped Ge—Te, (which may be useful as a phase change material is formed), it may be difficult to adjust a ratio of Ge and Te. For example, while N-doped Ge—Te (N—Ge—Te) is amorphous and may be conformally deposited when the content of Ge is relatively large, N-doped Ge (N—Ge), formed by bonding to N the Ge that remains unbonded to Te, is a nonconductor and has high resistance. Thus, if the content of the N—Ge of the phase change material is higher than that of the N—Ge—Te, resistance may undesirably increase. Thus, the phase change material may not be suitable for a PRAM. A phase change material layer may be formed by simultaneously providing a Ge(II) source and Te source. However, when a phase change material layer is formed by such simultaneous supply at a process temperature of, e.g., 300° C. or higher, a ratio of Te to Ge—Te may be greater than 50 percent. Thus, the general phase change material layer may become undesirably crystalline (see FIG. 3A). Further, although no void may be observed in a hole at an initial deposition, void(s) may be formed by annealing during a subsequent integration process. The phase change material layer formed according to an embodiment may not become crystalline and also may not form voids during subsequent manufacturing processes.

In contrast, according to embodiments, times of supplying the first source, containing germanium, and the second source, containing tellurium, may be controlled independently. In other words, the first source and the second source may be supplied to the substrate for different durations. Therefore, a ratio of Te to Ge—Te may be adjusted to below about 50 percent even at a high temperature, e.g., above about 300° C. In an implementation, the ratio of Te to Ge—Te may be adjusted to be, e.g., about 50 percent, less than 50 percent, or less than or equal to 50 percent. Thus, the phase change material may become amorphous and may be deposited minutely and conformally (see FIG. 3B, FIG. 6, and FIG. 9). Further, a void may not be formed even when annealing is conducted during a subsequent integration process. Accordingly, a contact area between a heating electrode and the phase change material layer may be reduced, thus increasing an effective current density and a magnitude of a write current during, e.g., reset programming.

Referring to FIGS. 10 to 13, a method of fabricating a phase change memory device according to an embodiment will now be described below in detail.

As illustrated in FIG. 10, a semiconductor substrate 101 including wordlines (not illustrated) and selection elements (not illustrated) may be provided. The wordlines may include a line-shaped impurity-doped region. The selection element may include a diode or a transistor. A first interlayer dielectric 110 may be formed on the semiconductor substrate 101.

A bottom electrode 112 may be formed on the first interlayer dielectric 110. The bottom electrode 112 may include, e.g., titanium, titanium nitride, titanium aluminum nitride, tantalum, tantalum nitride, tungsten, tungsten nitride, molybdenum nitride, niobium nitride, titanium silicon nitride, titanium boron nitride, zirconium silicon nitride, tungsten silicon nitride, tungsten boron nitride, zirconium aluminum nitride, molybdenum aluminum nitride, tantalum silicon nitride, tantalum aluminum nitride, titanium tungsten, titanium aluminum, titanium oxynitride, titanium aluminum oxynitride, tungsten oxynitride, and/or tantalum oxynitride.

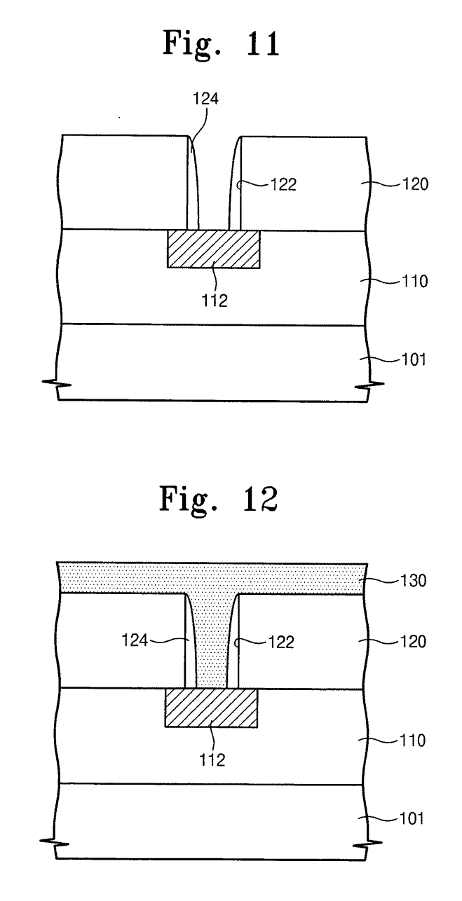

Referring to FIG. 11, an insulating layer 120 may be formed on the bottom electrode 112. The insulating layer 120 may be formed of, e.g., silicon oxide such as borosilicate glass (BSG), phosphosilicate glass (PSG), borophosphosilicate glass (BPSG), plasma-enhanced tetraethylorthosilicate (PE-TEOS), and/or high-density plasma (HDP).

An opening 122 may be formed in the insulating layer 120 to expose a portion of the bottom electrode 112. A spacer insulating layer (not illustrated) may be formed in the opening 122 and then anisotropically etched to expose the bottom electrode 112, thereby forming a spacer 124 on a sidewall of the opening 120. The spacer 124 may allow an effective size of the opening 120 to become smaller than a resolution limit of a photolithography process.

Referring to FIG. 12, a Ge—Sb—Te phase change material layer 130 may be formed by, e.g., atomic layer deposition (ALD), according to the above described embodiments to fill the opening 122. A process temperature may be about 300° C. to about 400° C. A thin film of amorphous Ge₁₋ₓTeₓ(0<x≦0.5) may be formed; and then a layer of amorphous Sb₁₋ₓTeₓ(0<x<1) may be formed thereon. Thus, a phase change material layer of N-doped amorphous Sb₁₋ₓTeₓ(0<x<1) may be formed. Since the phase change material layer may be an amorphous layer even at a high temperature, it may fill a minute and small-sized opening without an undesirable void.

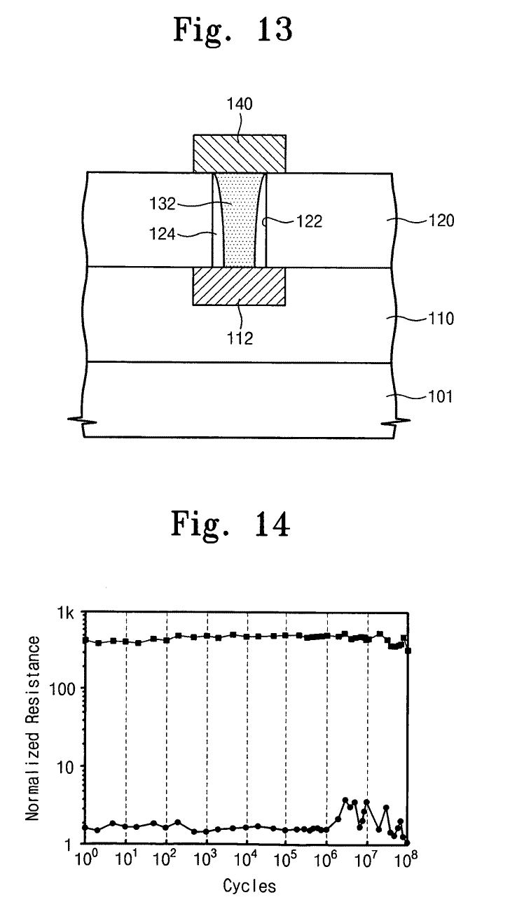

Referring to FIG. 13, the phase change material layer 130 may be planarized to form a phase change material pattern 132. A top electrode 140 may be formed on the phase change material pattern 132. The phase change material layer 130 may be planarized by, e.g., etch-back or chemical mechanical polishing (CMP). A phase change resistor may be formed, the phase change resistor including the bottom electrode 112, the top electrode 140, and the phase change material pattern 132 between the bottom and top electrodes 112 and 140.

A reliability of a phase change memory device according to an embodiment was estimated. Referring to FIG. 14, an excellent endurance was exhibited in which a constant resistance characteristic was maintained despite being cycled (i.e., set and reset) up to 10⁸ times.

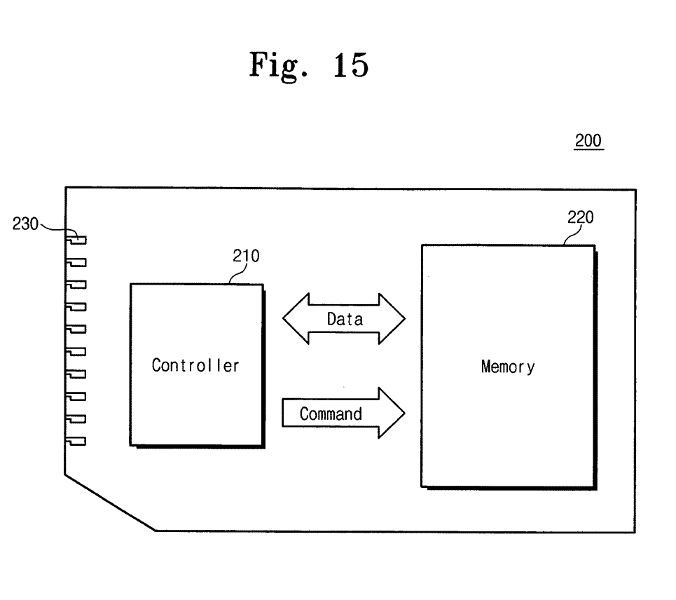

Referring to FIG. 15, a memory card system 200 including phase change memory devices according to an embodiment will now be described. The memory card system 200 may include a controller 210, a memory 220, and an interface 230. The controller 210 may include, e.g., a microprocessor, a digital signal processor, a microcontroller, or the like. The memory 220 may be used to, e.g., store a command executed by the controller 210 and/or user data. The memory 220 may include not only phase change memory devices formed according to the above described embodiments, but also, e.g., a random accessible nonvolatile memory device and/or various types of memory devices. The controller 210 and the memory 220 may be configured to transfer and receive the command and/or the data. The interface 230 may serve to input/output external data. The memory card system 200 may be, e.g., a multimedia card (MMC), a secure digital card (SD), or a portable data storage.

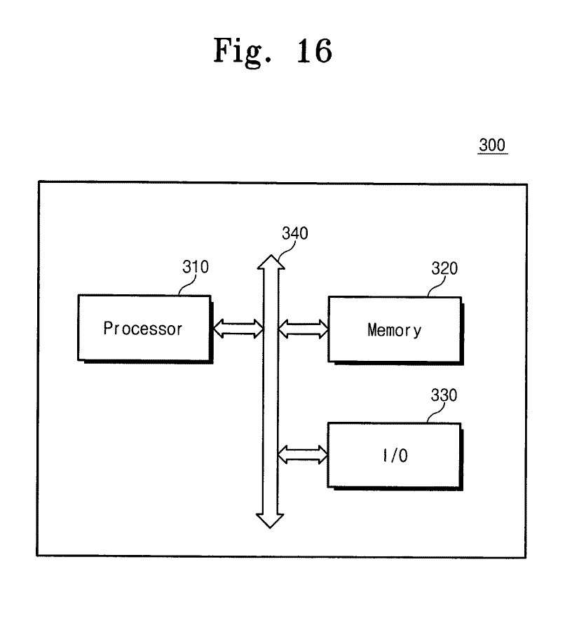

Referring to FIG. 16, an electronic system 300 including phase change devices according to an embodiment will now be described. The electronic system 300 may include a processor 310, a memory device 320, and an input/output device (I/O) 330. The processor 310, the memory device 320, and the I/O 330 may be connected through a bus 340. The memory 320 may receive control signals, e.g., RAS*, WE*, and CAS*, from the processor 310. The memory 320 may be used to store data accessed through the bus 340 and/or a command executed by the controller 310. The memory 320 may include a variable resistance memory device according to an embodiment. It will be appreciated by those skilled in the art that an additional circuit and control signals may be applied for detailed realization and modification of the embodiments.

The electronic system 300 may be used in, e.g., computer systems, wireless communication devices (e.g., personal digital assistants (PDA), laptop computers, web tablets, mobile phones, and cellular phones), digital music players, MP3 players, navigators, solid-state disks (SSD), household appliances, and/or any components capable of transmitting and receiving data in a wireless environment.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A method of forming a phase change material layer, the method comprising:
forming an amorphous germanium layer by supplying a germanium containing first source into a reaction chamber;
cutting off supplying the first source after forming the amorphous germanium layer; and
forming amorphous Ge₁₋ₓTeₓ (0<x≦0.5) such that forming the amorphous Ge₁₋ₓTeₓ (0<x≦0.5) includes supplying a tellurium containing second source into the reaction chamber after cutting off supplying the first source.

2. The method as claimed in claim 1, wherein the amorphous Ge₁₋ₓTeₓ (0<x≦0.5) is formed at a temperature of about 300° C. or greater.

3. The method as claimed in claim 2, wherein the amorphous Ge₁₋ₓTeₓ (0<x≦0.5) is formed at a temperature of about 300° C. to about 400° C.

4. The method as claimed in claim 1, wherein the first source includes at least one of an amide ligand, a phosphanido ligand, an alkoxide ligand, and a thiolate ligand.

5. The method as claimed in claim 4, further comprising supplying a reactive gas into the reaction chamber, the reactive gas including at least one of ammonia, primary amine, diazene, and hydrazine.

6. The method as claimed in claim 1, further comprising supplying an antimony containing third source into the reaction chamber.

7. The method as claimed in claim 6, wherein the third source is supplied after supplying the second source.

8. The method as claimed in claim 7, further comprising sequentially supplying additional second source and first source after supplying the third source.

9. The method as claimed in claim 7, further comprising supplying additional second source at the same time as supplying the third source.

10. The method as claimed in claim 6, wherein the third source and second source are supplied at the same time.

11. The method as claimed in claim 1, further comprising forming an amorphous layer of Sb₁₋ₓTeₓ (0<x<1) on the amorphous Ge₁₋ₓTeₓ (0<x≦0.5).

12. The method as claimed in claim 1, further comprising purging the reaction chamber between supplying sources.

13. (canceled)
